(19) United States
(12) Patent Application Publication
(10) Pub. No.: US 2006/0272577 A1
(43) Pub. Date: Dec. 7, 2006

(54) Method and apparatus for decreasing deposition time of a thin film

(76) Inventors: Ming Mao, Pleasanton, CA (US); Randhir Bubber, Fremont, CA (US); Thomas Andrew Schneider, Livermore, CA (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/145,273

(22) Filed: Jun. 3, 2005

(51) Int. Cl. C23C 16/00

(52) U.S. Cl. 118/715

(57) ABSTRACT

A method and apparatus for decreasing deposition time of a thin film are disclosed. The apparatus includes a removable shield assembly disposed in a vacuum chamber. The shield assembly forms an enclosure to house a substrate during an ALD process. A gas line coupled to the shield assembly introduces a gas into the enclosure to form a thin film on a surface of the substrate. A final valve is associated with the gas line and located proximate the shield assembly such that placement of the final valve with respect to the shield assembly provides fast delivery of the gas into the enclosure.

### TECHNICAL FIELD

The present disclosure generally relates to film deposition, and more particularly to a method and apparatus for decreasing deposition time of a thin film.

### BACKGROUND

Atomic layer deposition (ALD), also known as sequential pulsed chemical vapor deposition (SP-CVD), atomic layer epitaxy (ALE) and pulsed nucleation layer (PNL) deposition, has gained acceptance as a technique for depositing thin and continuous layers of metals and dielectrics with high conformality. In an ALD process, a substrate is alternately dosed with two or more reactants (e.g., a precursor and a reactive gas), interleaved with inert gas purging, so that the adsorptions and reactions are self-limited and only occur on the surface of a substrate. Thus, gas phase reactions are avoided since the reactants do not mix in the gas phase. Uniform adsorption of reactants on the wafer surface during the ALD process achieves a high density of nucleation sites and produces highly conformal layers at both microscopic feature length scales and macroscopic substrate length scales. These attributes result in the deposition of spatially uniform, conformal, dense and continuous thin films having thicknesses between a few Angstroms and a few micrometers.

The high quality films achievable by ALD have resulted in increased interest in ALD for the deposition of conformal barriers, high-k dielectrics, gate dielectrics, tunnel dielectrics and etch stop layers for semiconductor devices. ALD films are also thermally stable and very uniform which makes them attractive for optical applications. Another application for ALD is the deposition of oxides (e.g., Al₂O₃) as read gap layers for thin film heads, such as heads for recording densities of 50 Gb/in² and beyond which require very thin and conformal read gap layers.

Although an ALD process supports deposition of conformal, thin layers of a material, the process typically has a low average deposition rate due to the repeated cycles of pulsing reactants into the reaction chamber and purging the chamber between each reactant pulse. The repeated cycles are time consuming, which results in reduced throughput relative to conventional deposition techniques. The cycle time depends primarily on the design of the reaction chamber used to deposit the thin film. For example, the design of the reaction chamber may determine pulse times for delivering a sufficient dose of the reactants for surface saturation and the purge times to remove surplus reactants and byproducts for the prevention of gas phase reactions.

### SUMMARY

In accordance with the present disclosure, the disadvantages and problems associated with providing decreased cycle times for atomic layer deposition (ALD) have been substantially reduced or eliminated. In a particular embodiment, an apparatus is disclosed that includes a final valve located proximate a shield assembly such that the placement of the final valve provides fast delivery of a gas into an enclosure formed by the shield assembly.

In accordance with one embodiment of the present disclosure, an atomic layer deposition (ALD) apparatus for decreasing deposition time of a thin film includes a removable shield assembly disposed in a vacuum chamber. The shield assembly forms an enclosure to house a substrate during an ALD process. A gas line coupled to the shield assembly introduces a gas into an enclosure to form a thin film on a surface of the substrate. A final valve is associated with the gas line and located proximate the shield assembly such that placement of the final valve with respect to the shield assembly provides fast delivery of the gas into the enclosure.

In accordance with another embodiment of the present disclosure, an atomic layer deposition (ALD) method for decreasing deposition time of a thin film includes providing a substrate in a shield assembly disposed in a vacuum chamber such that the shield assembly forms an enclosure around the substrate. Gas is introduced into a gas line coupled to the shield assembly. The gas line includes a final valve located proximate the shield assembly such that placement of the final valve with respect to the shield assembly provides fast delivery of the gas into the enclosure. The final valve is opened to introduce the gas into the enclosure and gas is injected into the enclosure to form a thin film on a surface of the substrate.

In accordance with a further embodiment of the present disclosure, an atomic layer deposition (ALD) apparatus for decreasing deposition time of a thin film includes a removable shield assembly disposed in a vacuum chamber. The shield assembly forms an enclosure that houses a substrate during an ALD process. A gas line coupled to the shield assembly introduces a gas from a gas reservoir into the enclosure to form a thin film on a surface of the substrate. A final valve associated with the gas line is located proximate the shield assembly and a preliminary valve associated with the gas line is located between the gas reservoir and the final valve. Placement of the final valve with respect to the shield assembly provides fast delivery of the gas into the enclosure.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a schematic diagram of an atomic layer deposition (ALD) system for forming a thin film on a substrate according to teachings of the present disclosure;

FIG. 2 illustrates a schematic diagram of a shield assembly located in a vacuum chamber of the ALD system of FIG. 1 according to teachings of the present disclosure; and

FIG. 3 illustrates flow patterns over a substrate housed in the shield assembly of FIG. 2 according to teachings of the present disclosure.

### DETAILED DESCRIPTION

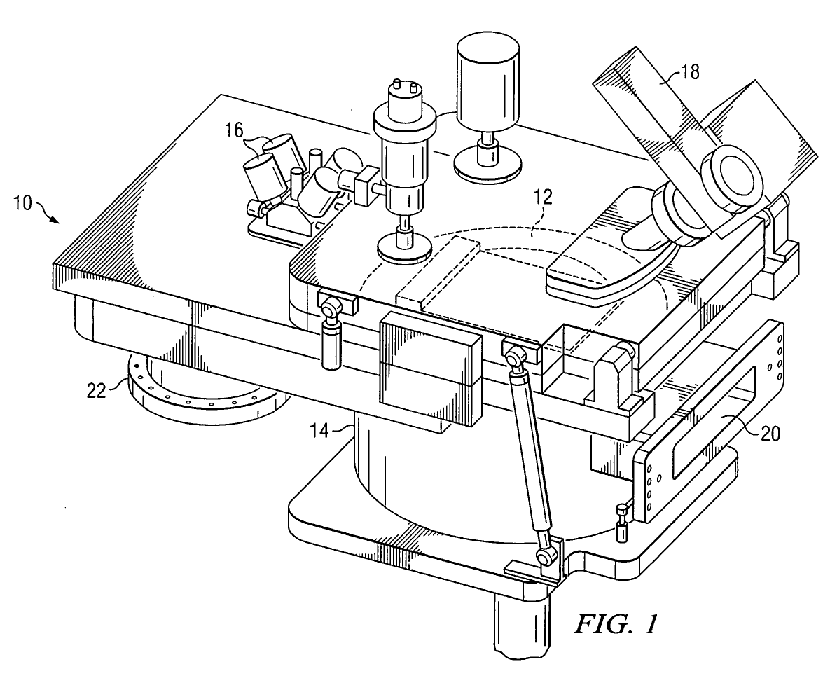

Preferred embodiments of the present disclosure and their advantages are best understood by reference to FIGS. 1 through 3, where like numbers are used to indicate like and corresponding parts.

The conceptual groundwork for the present disclosure involves an atomic layer deposition (ALD) process to create highly conformal thin films. In an ALD process, two or more reactants (e.g., a precursor or a reactant gas) are sequentially pulsed onto the surface of a substrate contained in an enclosure, and interleaved with inert gas purging without mixing the reactants in the gas phase. The precursor or reactant reacts on the surface of the substrate in such a way that a thin film of a material is formed by atomic layer growth. The introduction of the precursor or reactant into the reaction chamber may be referred to as a doping pulse. In between doping pulses, the reaction chamber may be purged by flowing an inert gas over the substrate (e.g., a purge pulse). The time needed to complete the doping and purge pulses may depend on the dose of the precursor or reactant injected into the enclosure.

The present disclosure provides an ALD apparatus that decreases the cycle time (e.g., the time to complete a doping pulse and a purge pulse) for an ALD process by increasing the dose of precursor or reactant introduced into the enclosure. The apparatus may include a shield assembly that is disposed in a vacuum chamber. The shield assembly forms an enclosure that houses a substrate during the ALD process. A gas line is coupled to the shield assembly for injecting the reactants and the purge gas into the enclosure formed by the shield assembly. A final valve may be associated with the gas line such that the final valve may be located proximate the shield assembly to provide fast delivery of the reactants into the enclosure. By increasing the dose of the reactants into the enclosure, the cycle time for deposition of the thin film may be decreased. Additionally, other valves associated with the gas line may be left open during the ALD process to ensure that the gas line is fully charged when the final valve is opened so that a sufficient amount of reactants is injected into the enclosure.

FIG. 1 illustrates atomic layer deposition (ALD) system 10 for reducing deposition time of a conformal thin film on a substrate. ALD system 10 may include shield assembly 12 located inside vacuum chamber 14, final gas valves 16a and 16b (generally referred to as final gas valves 16), isolation valves 18, substrate loader 20 and high pressure vacuum pump inlet 22. Shield assembly 12 may form an enclosure inside of vacuum chamber 14 such that the enclosure may contain a substrate for deposition of a thin film using an ALD process. In one embodiment, shield assembly 12 may be removable from vacuum chamber 14 such that all or portions of shield assembly 12 may be cleaned and/or replaced. The ability to remove and replace all or portions of shield assembly 12 may simplify and improve preventative maintenance and increase the time in between maintenance periods for ALD system 10.

Final gas valves 16 may interface with shield assembly 12 such that final gas valves 16 are located in close proximity to shield assembly 12. During an ALD process, a gas (e.g., reactants and/or an inert gas used to purge the enclosure) may be introduced into the enclosure from one or more gas reservoirs (not expressly shown) through one or both of final gas valves 16. In one embodiment, the gas reservoirs may contain a precursor or one or more reactants used during a doping pulse. In another embodiment, the gas reservoirs may contain an inert gas that is used as a carrier gas during a doping pulse and/or that is used to remove any remaining reactants from the enclosure during a purge pulse.

During an ALD process, at least one of final gas valves 16 may be opened to allow the reactants and/or inert gas to flow into the enclosure formed by shield assembly 12. More specifically, during a doping pulse, at least one of final gas valves 16 may be opened to allow the precursor or reactant to flow into shield assembly 12. Final gas valves 16 may be placed in close proximity to shield assembly 12 to allow for fast delivery of the precursors and reactants used to deposit the thin film. The doping pulse time may be decreased because when one or both of final gas valves 16 are opened the gas has a shorter distance to travel into shield assembly 12 and is fully charged when introduced into the enclosure formed by shield assembly 12, which may lead to an increased reactant dose and/or an increased partial pressure.

Additionally, placement of final gas valves 16 in close proximity to shield assembly 12 provides for a faster purge time. During a purge pulse, at least one of final gas valves 16 may be opened to introduce an inert gas into the enclosure formed by shield assembly 12 in order to remove any unreacted precursor or reactant gas. In one embodiment, the inert gas may be introduced through a gas line not used for the reactants such that final gas valve 16a is open when the reactants are introduced into the enclosure during a doping pulse and final gas valve 16b is open when the inert gas is introduced into the enclosure during a purge pulse. The purge time may be decreased because the small distance between final gas valves 16 and shield assembly 12 allows for a fast delivery of purge gas and a quick purge of any precursor or reactant remaining in the gas lines between final gas valves 16 and shield assembly from the preceding doping pulse. The latency between two sequential doping pulses, therefore, may also be reduced.

Although not expressly shown, a programmable logic controller (PLC) or any suitable real time controller may be interfaced with and/or integral to ALD system 10 in order to provide a short cycle time for the ALD process. The PLC may be used to control the opening and closing of final gas valves 16 in order to provide switching control during timing critical sections of the ALD process. In one embodiment, the PLC may be capable of switching control times of less than approximately fifty milliseconds (50 ms) in order to provide a faster ALD cycle time and, therefore, a higher deposition rate for the thin film formed on the surface of the substrate.

Isolation valves 18 may be interfaced with shield assembly 12 opposite final gas valves 16 in order to remove unreacted precursor and/or reactant and inert gas from the enclosure formed by shield assembly 12. Isolation valves 18 may further be coupled to a mechanical pump (not expressly shown) by a throttle valve (not expressly shown) that facilitates automated process pressure control during an ALD process. During a doping pulse, isolation valves 18 may be opened to allow the mechanical pump to pump the precursor or the reactant and any carrier gas through the enclosure. After the doping pulse is completed, a high speed turbo pump (not expressly shown) coupled to pump inlet 22 may be used to allow vacuum chamber 14 to quickly reach the base pressure. During a purge pulse, isolation valves 18 may be opened to allow the mechanical pump to remove any remaining precursor and/or reactant from the enclosure by pumping an inert gas through the enclosure. Use of only the mechanical pump during a doping pulse to exhaust the precursor or the reactant and the carrier gas from the enclosure, therefore, may extend the operation duration and life expectancy of the turbo pump. Additionally, the direct exhaust system provided by using the mechanical pump may allow for effective control of the ALD process in a pressure range from approximately five hundred (500) mTorr to approximately ten (10) Torr.

Substrates on which a thin film may be deposited may be loaded into vacuum chamber 14 (and into the enclosure formed by shield assembly 12) from a central wafer handler (not expressly shown) through substrate loader 20. In one embodiment, a substrate placed in vacuum chamber 14 may be a p-type or n-type silicon substrate. In other embodiments, the substrate may be formed from gallium arsenide, an AlTiC ceramic material or any other suitable material that may be used as a substrate on which one or more material layers may be deposited. The one or more layers deposited by ALD system 10 may form films used to fabricate conformal barriers, high-k dielectrics, gate dielectrics, tunnel dielectrics and barrier layers for semiconductor devices. ALD films are also thermally stable and substantially uniform, which makes them attractive for optical applications. Another application for ALD may be the deposition of oxides as a gap layer for thin film heads, such as heads for recording densities of approximately fifty (50) Gb/in² and beyond that require very thin and conformal gap layers, as a barrier layer for a tunnel MagnetoResistive (TMR) type read head, as an isolation layer on an abut junction to insulate a TMR or Current-Perpendicular-to-Plane (CPP) type read head from hard bias layers, or as an encapsulation layer to protect the Longitudinal Magnetic Recording (LMR) and, in particular, the Perpendicular Magnetic Recording (PMR) write pole from corrosion. Additionally, ALD thin films may be used to form structures with high aspect ratios, such as MicroElectroMechanical (MEM) structures.

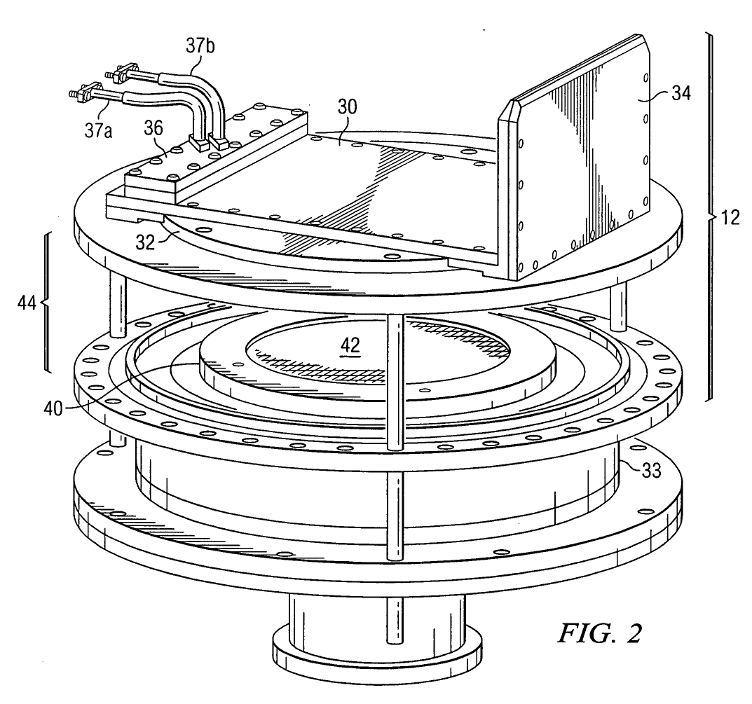

FIG. 2 illustrates shield assembly 12 that cooperates with top hat 40 to form enclosure 44 located inside vacuum chamber 14. In the illustrated embodiment, shield assembly 12 includes top shield 30, bottom shield 32, vertical shield 34 and diffuser plate 36 that may be coupled together and mounted on a frame. Shield assembly 12 may facilitate preventative maintenance of ALD system 10 because portions of shield assembly 12 (e.g., top shield 30, bottom shield 32, etc.) may be individually removed and cleaned or replaced as necessary.

Top hat 40 may include substrate seat 42 for holding a substrate on which a thin film is to be deposited. Substrate seat 42 may have a depth slightly greater than or approximately equal to the thickness of a substrate. In one embodiment, substrate seat 42 may be a recess formed in top hat 40 such that substrate seat 42 is integral to top hat 40. In another embodiment, substrate seat 42 may be mounted on top hat 40 such that substrate seat 42 is separate from top hat 40. Top hat 40 may be mounted on chuck 38 located in vacuum chamber 14. Chuck 38 may function to control the position of substrate seat 42 within vacuum chamber 14 and the position of top hat 40 in relation to shield assembly 12. In one embodiment, chuck 38 includes a heating mechanism with temperature control and constant backside gas flow to a substrate located in substrate seat 42. The temperature control with constant backside gas flow may ensure fast heating and temperature uniformity across a substrate positioned in substrate seat 42. In another embodiment, chuck 38 includes a RF power application mechanism, which allows in-situ RF plasma processing.

Enclosure 44 may be defined by the position of shield assembly 12 in relation to top hat 40. In one embodiment, enclosure 44 may be formed when top hat 40 is in contact with bottom shield 32 such that enclosure 44 has a volume defined by substrate seat 42 and the thickness of bottom shield 32. When top hat 40 is contacting bottom shield 32 of shield assembly 12, the volume of enclosure 44 may be approximately three (3) to approximately five (5) times greater than the volume of the substrate. Deposition of the thin film on the substrate may occur on the entire substrate surface without edge exclusion but may be confined only to enclosure 44. By minimizing the volume of enclosure 44, a minimum amount of precursor may be efficiently distributed in a minimum amount of time over the entire surface of the substrate. Additionally, surplus reactants and any reaction byproducts may be quickly removed from enclosure 44 to reduce the possibility of unwanted reactions from occurring inside enclosure 44.

In another embodiment, enclosure 44 may have a volume approximately equal to the volume of vacuum chamber 14 when chuck 38 is in the loading position (e.g., chuck 38 is at its lowest position in vacuum chamber 14). In other embodiments, the volume of enclosure 44 may depend on the distance between bottom shield 32 and top hat 40 such that the volume is varied between approximately fifty milliliters (50 ml) when top hat 40 is in close proximity to bottom shield 32 of shield assembly 12 to approximately twenty liters (20 l) when chuck 38 is in the substrate loading position.

Gas lines 37a and 37b (generally referred to as gas lines 37) may be respectively connected to final gas valves 16a and 16b as shown in FIG. 1. During either a doping or a purge pulse, one or more of final gas valves 16 may be opened to allow a gas to flow through one or both of gas lines 37 from gas reservoirs (not expressly shown). The gas then flows through diffuser plate 36 that is connected to gas lines 37 such that the gas flows into a gas injector (not expressly shown) located between diffuser plate 36 and top shield 30. In one embodiment, gas lines 37 may be formed of stainless steel and have a diameter of approximate one-quarter (¼ ) inch. Although the illustrated embodiment shows a particular number of gas lines, ALD system 10 may include any number of gas lines and any number of gas reservoirs. For example, a single gas line may be connected to multiple gas reservoirs such that the gas flowing through the gas line is controlled by one or more valves. In another embodiment, a separate gas line may be provided for each gas reservoir.

A thin film may be formed on a substrate located in substrate seat 42 by alternately flowing two or more precursors or reactants combined with an inert gas during a doping pulse and the inert gas during a purge pulse through gas lines 37 and into enclosure 44. For example, the precursor or reactant may be introduced into enclosure 44 through gas lines 37 and a monolayer of the precursor or reactant may be physisorbed or chemisorbed onto the surface of a substrate to form a thin film. Enclosure 44 may be purged by flowing an inert gas through gas lines 37 and into enclosure 44 to remove any remaining precursor. After purging, a second precursor or reactant be introduced into enclosure 44 through gas lines 37 and may combine with the absorbed monolayer of the first precursor or reactant to form a fraction or an atomic layer of the desired thin film. Again, enclosure 44 may be purged to remove any of the remaining reactant. The doping and purge pulses may be repeated until a thin film having the desired thickness is formed on the substrate.

As illustrated, the reactants and/or inert gas may be injected into enclosure 44 from one end of top shield 30 and exhausted at the other end through vertical shield 34. Vertical shield 34 may be coupled to isolation valves 18 (as illustrated in FIG. 1) and a mechanical pump (not expressly shown) that assists with the removal of the reactants and/or inert gas from enclosure 44.

ALD system 10 may also include one or more preliminary valves (not expressly shown) associated with gas lines 37. The preliminary valves may be located along gas lines 37 at any position such that the preliminary valves are located between the gas reservoirs coupled to gas lines 37 and final gas valves 16. In one embodiment, the preliminary valves may remain open during the ALD process to ensure that gas lines 37 are fully charged such that a sufficient amount of precursor and/or reactant may be injected into enclosure 44 when final gas valves 16 are opened. By ensuring that gas lines 37 are fully charged before each doping pulse begins, a faster reactant doping pulse time may be obtained by providing a sufficiently high reactant partial pressure. Additionally, the preliminary valves may not need to be serviced as often as if the valves were opened and closed during each doping pulse and purge pulse, which reduces the operation cost and extends the preventative maintenance period for ALD system 10. The number of preliminary valves associated with gas lines 37 may be varied such that each of gas lines 37 includes one or more preliminary valves, where each of the preliminary valves are located between the gas reservoirs and final gas valves 16.

In one embodiment, a layer of aluminum oxide (Al₂O₃) may be deposited using ALD system 10 with an ALD cycle time of less than approximately two seconds (2 sec). The deposited thin film using a fast cycle ALD process may have excellent film thickness uniformity such that within substrate uniformity values are less than approximately 1.2% 3σ and substrate-to-substrate repeatability values are less than approximately 0.2% 3σ for substrates having diameters of between approximately 100 mm and 300 mm. For cycle times of between one to two seconds, the deposition rate may be approximate 90 Å/minute. In a specific embodiment, a layer of Al₂O₃ may be deposited with an ALD cycle time of approximately 0.5 seconds and a deposition rate of approximately 120 Å/minute. An Al₂O₃ thin film manufactured in ALD system 10 with a cycle time of approximately 0.5 seconds may have within substrate uniformity values of less than approximately 1.0% 3a and substrate-to-substrate repeatability values of less than approximately 1.0% 3σ. In an another specific embodiment, a layer of Al₂O₃ may be deposited with an ALD cycle time of approximately 0.35 seconds and a deposition rate of approximately 170 Å/minute. An Al₂O₃ thin film manufactured with a cycle time of approximately 0.35 seconds may have a within substrate uniformity value of approximately 4.5% 3σ and substrate-to-substrate repeatability values of less than approximately 3.0% 3σ.

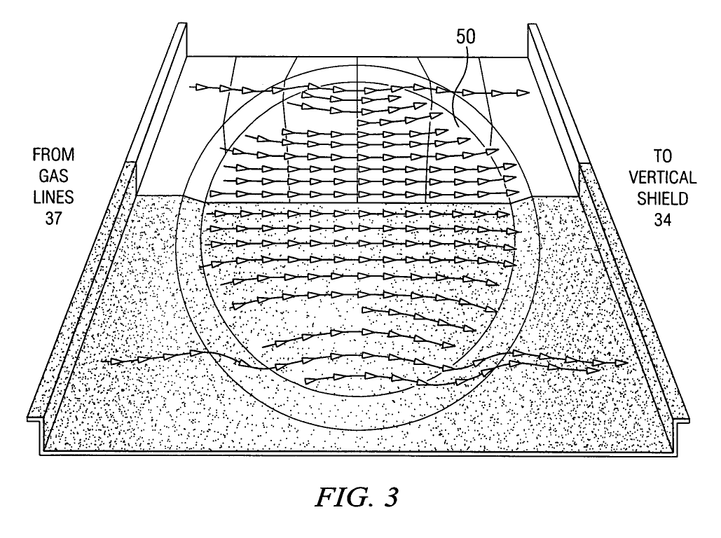

FIG. 3 illustrates illustrate flow patterns over a substrate located in enclosure 44 of ALD system 10 during an ALD process. Specifically, the flow pattern of a gas flowing over substrate 50 located inside enclosure 44 is illustrated at a flow rate of greater than approximately 500 sccm as calculated by a commercially available computational flow dynamics software (e.g., software developed and sold by CFDRC corporation of Huntsville, Alabama). A gas may be introduced into a gas injector (not expressly shown) interfaced with gas lines 37 and into enclosure 44. At the flow rate, the gas flows substantially uniformly over substrate 50 and is exhausted through vertical shield 34. As shown, the gas flow is laminar over the entire surface of substrate 50 without any turbulence. The laminar gas flow may be provided by the geometry of shield assembly 12 that forms enclosure 44. The characteristics of shield assembly 12 may make it possible to flow a minimal amount of reactant into enclosure 44, which may be efficiently distributed in a minimal amount of time over the substrate surface, and to quickly remove any surplus reactant and reaction byproducts.

Although the present disclosure as illustrated by the above embodiments has been described in detail, numerous variations will be apparent to one skilled in the art. For example, any type and/or number of valves that control fluid flowing through a gas line may be used. These valves may be positioned at any point along the gas lines such that the final valves are located in close proximity to a shield assembly forming an enclosure to allow for a fast delivery time for the gas when the final vales are opened and for a reduced latency between consecutive reactant doping pulses. Additionally, the shield assembly may have any shape that forms an enclosure to house a substrate. For example, the top shield may be a square or a circle, the bottom shield may be rectangular and the top hat may be rectangular so long as the various components cooperate to form an enclosure that houses a substrate. It should be understood that various changes, substitutions and alternations can be made herein without departing from the spirit and scope of the disclosure as illustrated by the following claims.

What is claimed is:

1. An atomic layer deposition (ALD) apparatus for decreasing deposition time of a thin film, comprising:
a removable shield assembly disposed in a vacuum chamber, the shield assembly forming an enclosure to house a substrate during an ALD process;
a gas line coupled to the shield assembly, the gas line operable to introduce a gas into the enclosure to form a thin film on a surface of the substrate; and
a final valve associated with the gas line and located proximate the shield assembly;
wherein placement of the final valve with respect to the shield assembly provides fast delivery of the gas into the enclosure.

2. The apparatus of claim 1, wherein the enclosure comprises a volume slightly greater than the substrate to provide laminar gas flow over the surface of the substrate.

3. The apparatus of claim 2, wherein the volume of the enclosure is between approximately three and approximately five times greater than a substrate volume.

4. The apparatus of claim 1, wherein:
the thin film comprises aluminum oxide; and
a cycle time for deposition of the thin film is between approximately 0.35 seconds and approximately 2.0 seconds.

5. The apparatus of claim 1, wherein:
the thin film comprises aluminum oxide; and
a deposition rate for the thin film is between approximately 90 Å/min and approximately 170 Å/min.

6. The apparatus of claim 1, further comprising:
a gas reservoir coupled to the gas line opposite the shield assembly, the gas reservoir operable to store the gas; and
a preliminary valve associated with the gas line, the preliminary valve located between the gas reservoir and the final valve;
wherein the preliminary valve remains open during the ALD process such that the gas line is fully charged to allow a sufficient amount of the gas to be injected into the enclosure when the final valve is open.

7. The apparatus of claim 1, wherein the shield assembly comprises:
a top shield including a top surface and a bottom surface;
a bottom shield including an aperture formed therein and a thickness, the bottom shield coupled to the bottom surface of the top shield such that the top shield covers the aperture;
a substrate holder operable to hold the substrate, the substrate holder in contact with the bottom shield such that the enclosure is formed having a volume defined by the aperture and the thickness of the bottom shield.

8. The apparatus of claim 1, further comprising a programmable logic controller (PLC) associated with the final valve to control timing of opening and closing of the final valve.

9. An atomic layer deposition (ALD) method for decreasing deposition time of a thin film, comprising:
providing a substrate in a shield assembly disposed in a vacuum chamber, the shield assembly forming an enclosure around the substrate;
introducing a gas into a gas line coupled to the shield assembly and including a final valve located proximate the shield assembly;
opening the final valve to introduce the gas into the enclosure, placement of the final valve with respect to the shield assembly providing fast delivery of the gas into the enclosure; and
injecting the gas into the enclosure to form a thin film on a surface of the substrate.

10. The method of claim 9, wherein the enclosure comprises a volume slightly greater than the substrate to provide laminar gas flow over the surface of the substrate.

11. The method of claim 9, wherein:
the thin film comprises aluminum oxide; and
a cycle time for deposition of the thin film is between approximately 0.35 seconds and approximately 2.0 seconds.

12. The method of claim 9, wherein:
the thin film comprises aluminum oxide; and
a deposition rate for the thin film is between approximately 90 Å/min and approximately 170 Å/min.

13. The method of claim 9, wherein the gas line further comprises a preliminary valve located between the final valve and a gas reservoir containing the gas, the preliminary valve remaining open when the gas is introduced into the gas line such that the gas line is fully charged to allow a sufficient amount of the gas to be injected into the enclosure when the final valve is open.

14. The method of claim 9, wherein opening the final valve comprises controlling timing of the opening with a programmable logic controller (PLC) associated with the final valve.

15. An atomic layer deposition (ALD) apparatus for decreasing deposition time of a thin film, comprising:
a removable shield assembly disposed in a vacuum chamber, the shield assembly forming an enclosure to house a substrate during an ALD process;
a gas line coupled to the shield assembly, the gas line operable to introduce a gas from a gas reservoir into the enclosure to form a thin film on a surface of the substrate;
a final valve associated with the gas line located proximate the shield assembly, placement of the final valve with respect to the shield assembly providing fast delivery of the gas into the enclosure; and
a preliminary valve associated with the gas line located between the gas reservoir and the final valve.

16. The apparatus of claim 15, wherein the enclosure comprises a volume slightly greater than the substrate to provide laminar gas flow over the surface of the substrate.

17. The apparatus of claim 15, wherein:
the thin film comprises aluminum oxide; and
a cycle time for deposition of the thin film is between approximately 0.35 seconds and approximately 2.0 seconds.

18. The apparatus of claim 15, wherein:
the thin film comprises aluminum oxide; and
a deposition rate for the thin film is between approximately 90 Å/min and approximately 170 Å/min.

19. The apparatus of claim 15, wherein the preliminary valve remains open during a deposition cycle such that the gas line is fully charged to allow a sufficient amount of the gas to be injected into the enclosure when the final valve is open.

20. The apparatus of claim 15, wherein the shield assembly comprises:
a top shield including a top surface and a bottom surface;
a bottom shield including an aperture formed therein and a thickness, the bottom shield coupled to the bottom surface of the top shield such that the top shield covers the aperture;
a substrate holder operable to hold a substrate, the substrate holder in contact with the bottom shield such that the enclosure is formed having a volume defined by the aperture and the thickness of the bottom shield.

21. The apparatus of claim 15, further comprising a programmable logic controller (PLC) associated with the final valve to control timing of opening and closing of the final valve.
